(19) United States
(12) Patent Application Publication
(10) Pub. No.: US 2008/0142954 A1
(43) Pub. Date: Jun. 19, 2008

(54) Multi-chip package having two or more heat spreaders

(76) Inventor: Chuan Hu, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/641,164

(22) Filed: Dec. 19, 2006

(51) Int. Cl. H01L 23/34

(52) U.S. Cl. 257/713; 257/E23.08

(57) ABSTRACT

A multi-chip package may include at least one integrated circuit die disposed on a substrate, and a local heat spreader is thermally coupled with the die. A global heat spreader is thermally coupled with this local heat spreader. The global heat spreader may also be coupled with one or more other local heat spreaders that are each coupled with another die disposed in the multi-chip package. Other embodiments are described and may be claimed.

### FIELD OF THE INVENTION

The disclosed embodiments relate generally to the cooling of integrated circuit (IC) devices, and more particularly to a multi-chip package having two or more heat spreaders.

### BACKGROUND OF THE INVENTION

Multi-chip assemblies can provide greater integration and enhanced function in a single package. Integration of IC devices fabricated using different process flows into a single package is possible, and can pave the way for system-in-package (SIP) solutions. In addition to the aforementioned benefits, these SIP or multi-chip packages may provide for reduced form factors, perhaps including both a smaller overall height as well as a smaller footprint (e.g., the surface area occupied by the package on a next-level component, such as a circuit board), as compared to a similar system having multiple, separate components mounted on a circuit board or other substrate.

One challenge facing manufacturers of multi-chip packages is cooling these devices during operation. Heat removal considerations may be especially acute where two or more processing devices are integrated in a single package (e.g., two or more microprocessors, a combination of a microprocessor and a graphics processor, etc.). A failure to adequately remove heat from a multi-chip package during operation may lead to reliability and performance deficiencies, and perhaps device failure. Issues that may arise in designing a cooling solution for a multi-chip package include mismatches in the coefficients of thermal expansion (CTE), thermally induced stresses (especially where low-k dielectric materials and/or lead-free interconnects are employed), compatibility with existing assembly processes and tools, integration of two or more die having differing process flows and perhaps varying thicknesses and sizes, and cost.

### BRIEF DESCRIPTION OF THE DRAWINGS

FIG. 1 is a schematic diagram illustrating an embodiment of a multi-chip assembly having two or more heat spreaders.

FIG. 2 is a block diagram illustrating an embodiment of a method of fabricating a multi-chip assembly having two or more heat spreaders.

FIGS. 3A-3H are schematic diagrams illustrating embodiments of the method shown in FIG. 2.

### DETAILED DESCRIPTION OF THE INVENTION

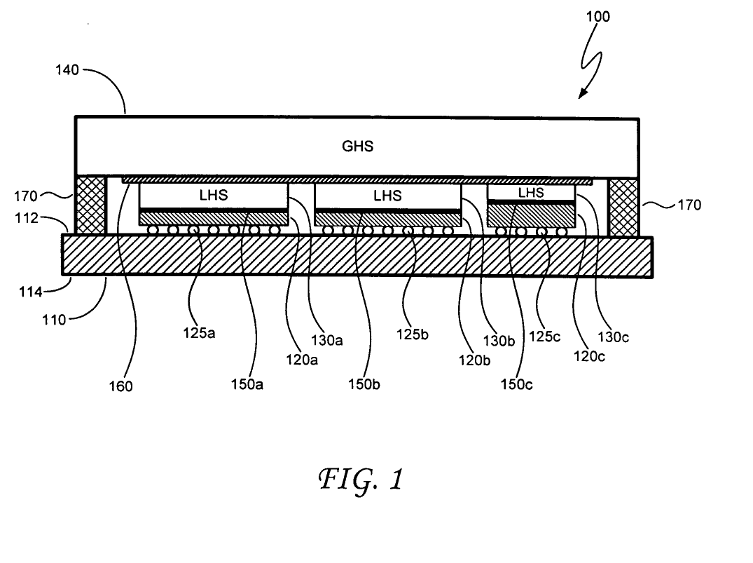

Referring to FIG. 1, illustrated is a multi-chip package 100. The multi-chip package 100 includes a substrate 110, a first integrated circuit (IC) die 120a, a second IC die 120b, and a third IC die 120c. A first local heat spreader (LHS) 130a is coupled with the first IC die 120a. Similarly, a second LHS 130b is coupled with the second die 120b, and a third LHS 130c is coupled with the third die 120c. Disposed over and coupled with each LHS 130a, 130b, 130c is a global heat spreader (GHS) 140. The use of one or more local heat spreaders in combination with a global heat spreader can enable the integration of die fabricated from different process flows and perhaps having varying sizes, can increase package stiffness and reduce warpage (which may be beneficial where thin die are employed, where low-k dielectric materials are present, and/or where lead-free interconnect materials are utilized), and may be compatible with existing processes and/or tools. Embodiments of the multi-chip package 100 having one or more local heat spreaders in combination with a global heat spreader, as well as embodiments of a method of fabricating such a package, are described in greater detail below.

The substrate 110 may comprise any suitable type of package substrate or other die carrier. In one embodiment, the substrate 110 comprises a multilayer substrate including a number of alternating layers of metallization and dielectric material. Each layer of metallization comprises a number of conductors (e.g., traces), and these conductors may comprise any suitable conductive material, such as copper. Further, each metal layer is separated from adjacent metal layers by the dielectric layers, and adjacent metal layers may be electrically interconnected by conductive vias. The dielectric layers may comprise any suitable insulating material—e.g., polymers, including both thermoplastic and thermosetting resins or epoxies, ceramics, etc.—and the alternating layers of metal and dielectric material may be built-up over a core layer of a dielectric material (or perhaps a metallic core).

The substrate includes a first side 112 and an opposing second side 114. A number of lands (not shown in figures) or other electrically conductive terminals are disposed on the substrate's first side 112, and these lands are arranged to couple with a number of metal bumps or columns 125a, 125b, 125c (or other electrically conductive terminals) extending from each of the IC die 120a, 120b, 120c, respectively. The substrate lands (or other terminals) are electrically coupled—as by, for example, a reflow process—with the die bumps (or other terminals) to form electrically conductive interconnects between the substrate 110 and each die 120a, 120b, 120c. It should be understood that other types of electrically conductive leads or terminals (e.g., wirebonds, etc.) may also be utilized to form interconnects between one or more of the IC die 120a-c and the substrate 110. Also, in a further embodiment, a layer of an underfill material (not shown in figures) may be disposed between each die 120a-c and the substrate 110.

A number of electrically conductive terminals (not shown in figures), such as metal bumps, columns, pins, etc., may also be disposed on the substrate's second side 114. The electrically conductive terminals on the substrate's opposing side 114 may be used to electrically couple the multi-chip package 100 with a next-level component, such as a printed circuit board (e.g., a motherboard), etc.

The IC die 120a, 120b, 120c may each comprise any desired integrated circuit device. In one embodiment, at least one of the IC die 120a-c comprises a processing device, such as a microprocessor, a graphics processor, an application specific integrated circuit (ASIC), a field programmable gate array (FPGA), etc. In another embodiment, at least one of the IC die 120a-c comprises a memory device, such as any type of dynamic random access memory (DRAM), a flash memory, etc. It should be understood that these are but a few examples of the types of IC devices that can be incorporated into the multi-chip package 100 and, further, that the package 100 may include other types of IC devices (e.g., a wireless communications device, a chip set, a MEMS device, a memory controller, etc.).

Any desired combination of IC devices may be disposed in the multi-chip package 100. By way of example, the multi-chip package may contain two (or more) processing devices (e.g., two microprocessors, a microprocessor and a graphics processor, etc.), a combination of one or more processing devices and one or more memory device, a combination of one or more processing devices and one or more wireless communication device, as well as any other suitable combination of devices. In addition, it should be noted that the multi-chip package 100 may include one or more passive devices (not shown in figures), such as capacitors, inductors, etc.

In one embodiment, the IC die 120a-c may all have the same thickness and footprint (e.g., length and width). However, in another embodiment, one or more of the IC die 120a-c may be different in size, and such an embodiment is illustrated in FIG. 1. In the embodiment of FIG. 1, the IC die 120c has a greater thickness than either of the IC die 120a or 120b (and also has a different footprint). The IC die 120a-c may have any suitable thickness, and in one embodiment any one or more of the IC die 120a-c may be thinned prior to bonding with an LHS (and/or prior to attachment to substrate 110). According to one embodiment, any one or more of the IC die 120a-c has a thickness in a range of between approximately 10 μm and 150 μm. In a further embodiment, any one or more of the IC die 120a-c has a thickness in a range up to approximately 50 μm.

Generally, according to one embodiment, each LHS 130a, 130b, 130c comprises any device capable of receiving heat from the attached IC die 120a, 120b, 120c, respectively, and transferring at least some of this heat to the GHS 140. In one embodiment, each LHS 130a-c comprises a block of thermally conductive material (of any suitable shape) having one surface capable of being thermally coupled with an IC die and an opposing surface capable of being thermally coupled with the GHS 140. According to one embodiment, the thermally conductive material comprises copper or an alloy of copper. However, the disclosed embodiments are not limited to the use of copper, and it should be understood that an LHS may comprise any other suitable thermally conductive material (e.g., diamond, silicon carbide, copper tungsten, aluminum, etc.) or combination of materials.

A local heat spreader may have any suitable size and shape. According to one embodiment, one or more of the local heat spreaders 130a-c comprises a shape that is substantially congruent with the shape of it's mating IC die 120a-c, respectively. In another embodiment, one or more of the local heat spreaders 130a-c comprises a shape having a perimeter (or at least one edge) that extends beyond—perhaps just slightly beyond, or in another embodiment substantially beyond—the footprint (or at least one edge) of the underlying mating die 120a-c, respectively. In one embodiment, an LHS has a thickness that is between approximately 10 and 20 times the thickness of that LHS's mating die. In a further embodiment, an LHS has a thickness in a range of between approximately 300 μm and 1.5 mm.

A local heat spreader may be bonded to a mating IC die using any suitable device or process. According to one embodiment, each LHS 130a-c is thermally (and mechanically) coupled with its mating IC die 120a-c, respectively, by a layer of thermal interface material (TIM). As shown in FIG. 1, a first TIM layer 150a is disposed between the first IC die 120a and the first LHS 130a, a second TIM layer 150b is disposed between the second die 120b and the second LHS 130b, and a third TIM layer 150c is disposed between the third die 120c and the third LHS 130c. The TIM layers 150a-c may comprise any suitable material or combination of materials that performs any one or more of the following: (1) adheres to both the LHS (e.g., copper) and the mating die (e.g., silicon); (2) acts as a diffusion barrier to copper or other LHS material (to prevent copper or other metal migration into the die); (3) provides a sufficient thermal and mechanical bond between the LHS and die; and (4) inhibits surface oxidation.

Any one or more of the TIM layers 150a-c may comprises a single layer of material or multiple, discrete layers of material (whether the same or different). Materials believed suitable for use as a TIM, whether alloyed together or present in discrete layers, include tin, nickel, gold, copper, and solders, as well as thermally conductive polymers. The TIM layers 150a-c may have any suitable thickness, and in one embodiment a TIM layer may have a thickness in a range between approximately 1 μm and 10 μm. The thermal interface materials may be disposed on each die 120a-c (and/or on each LHS 130a-c) using any suitable process, such as a physical vapor deposition (PVD) process, a chemical vapor deposition (CVD) process, an electroplating process, or an electroless plating process (or any combination of these or other processes). In one embodiment, a thermal interface material is applied to a die at the wafer level prior to dicing.

The local heat spreaders 130a-c may be fabricated by any suitable processes or combination of processes. For example, an LHS may be fabricated by machining (e.g., milling, laser machining, etc.), stamping, or molding, as well as any combination of these and/or other processes. Also, in one embodiment, a number of local heat spreaders may be disposed in an array (perhaps fabricated from a single sheet of copper or other material) and held in a carrier. In this embodiment, the LHS array may be disposed over a mating array of singulated die, and bonding between the local heat spreaders and die may be performed on the entire array (e.g., wafer level bonding).

Generally, according to one embodiment, the GHS 140 comprises any device capable of receiving heat from the attached local heat spreaders 130a, 130b, 130c, respectively, and transferring or otherwise dissipating at least some of this heat to the surrounding environment (perhaps with the assistance of an active cooling device, such as a fan, or another passive cooling device, such as a multi-fin heat sink). In one embodiment, the GHS 140 comprises a block of thermally conductive material (of any suitable shape) having a surface capable of being thermally coupled with each of the local heat spreaders 130a-c. In a further embodiment, the GHS includes a surface capable of being thermally coupled with another passive cooling device (e.g., a heat sink) or an active cooling device (e.g., a fan).

According to one embodiment, the GHS 140 comprises copper or an alloy of copper. However, the disclosed embodiments are not limited to the use of copper, and it should be understood that the GHS may comprise any other suitable thermally conductive material (e.g., diamond, silicon carbide, copper tungsten, aluminum, etc.) or combination of materials. Also, in one embodiment, the GHS 140 and the LHS's 130a-c comprise the same material, such as copper. However, in another embodiment, the GHS 140 may comprise a first thermally conductive material, and any one or more of the LHS's 130a-c may comprise a second, different thermally conductive material. It should be noted that, in one embodiment, the LHS's 130a-c comprise the same material, but in other embodiments, any one of the LHS's 130a-c may comprise a material that is different from that of the remaining local heat spreaders.

The global heat spreader may have any suitable size and shape. Generally, the surface of the GHS 140 facing the local heat spreaders 130a-c should have a size and shape such that the perimeter of each LHS lies within a perimeter of the GHS. Also, the GHS may have any suitable thickness, and in one embodiment the GHS has a thickness in a range of between approximately 1 mm and 2 mm. The GHS 140 may be fabricated by any suitable processes or combination of processes. For example, the GHS may be fabricated by machining (e.g., milling, laser machining, etc.), stamping, or molding, as well as any combination of these and/or other processes.

The GHS 140 may be bonded to the underlying local heat spreader 130a-c using any suitable device or process. According to one embodiment, the GHS 140 is thermally (and mechanically) coupled with each LHS 130a-c by a TIM layer 160, as shown in FIG. 1. In one embodiment, the TIM 160 comprises any suitable material or combination of materials that sufficiently adheres to both the GHS and the mating LHS's 130a-c (e.g., all copper) and, further, that provides a sufficient thermal and mechanical bond between the GHS and the local heat spreaders. Also, the TIM 160 may comprise a single layer of material or multiple, discrete layers of material (whether the same or different). Materials believed suitable for use as a TIM 160, whether alloyed together or present in discrete layers, include tin, nickel, gold, copper, and solders, as well as thermally conductive polymers. The TIM 160 may have any suitable thickness, and in one embodiment this layer has a thickness in a range between approximately 5 μm and 25 μm (e.g. for polymers), whereas in another embodiment this layer has a thickness in a range between approximately 25 μm and 50 μm (e.g., for solders or other metals). The TIM 160 may be disposed on the GHS 140 (or, alternatively, on each LHS 130a-c) using any suitable process, such as a PVD process, a CVD process, an electroplating process, or an electroless plating process (or any combination of these or other processes).

In one embodiment, a spacer and/or seal 170 is disposed between the GHS 140 and the substrate 110. The spacer 170 may comprise any suitable material (e.g., a polymer), and this component may be attached to both the GHS 140 and substrate 110 by any suitable method (e.g., using an epoxy or other adhesive). In another embodiment, the spacer 170 simply comprises a layer or bead of epoxy bonding the GHS 140 to the substrate 110. In yet another embodiment, the spacer 170 forms part of the GHS 140 and comprises a lip disposed about the periphery of the GHS and extending toward the substrate 110 (and this lip may have a lower surface bonded to the substrate by any suitable method, such as by an epoxy or other adhesive).

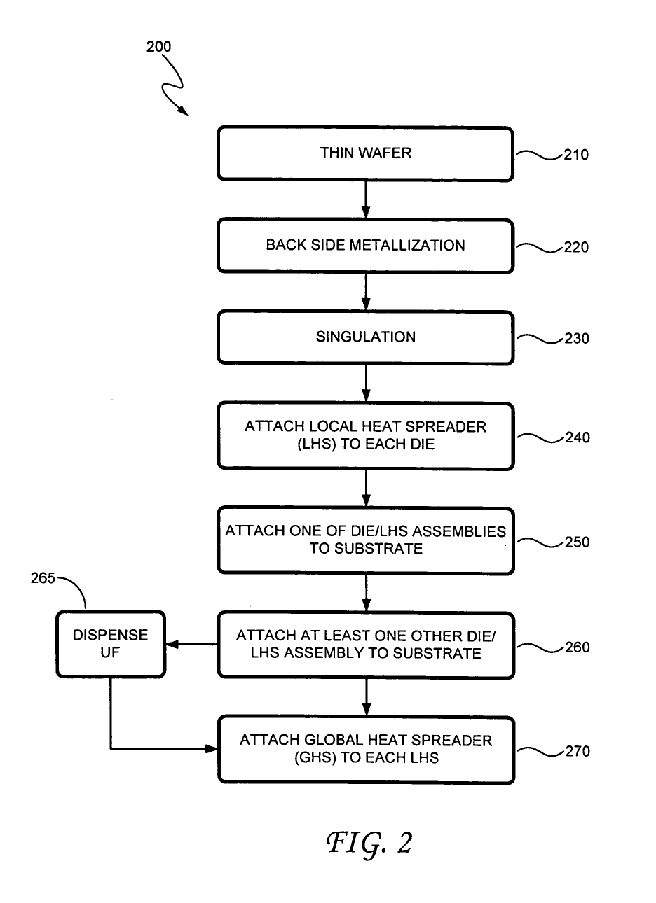

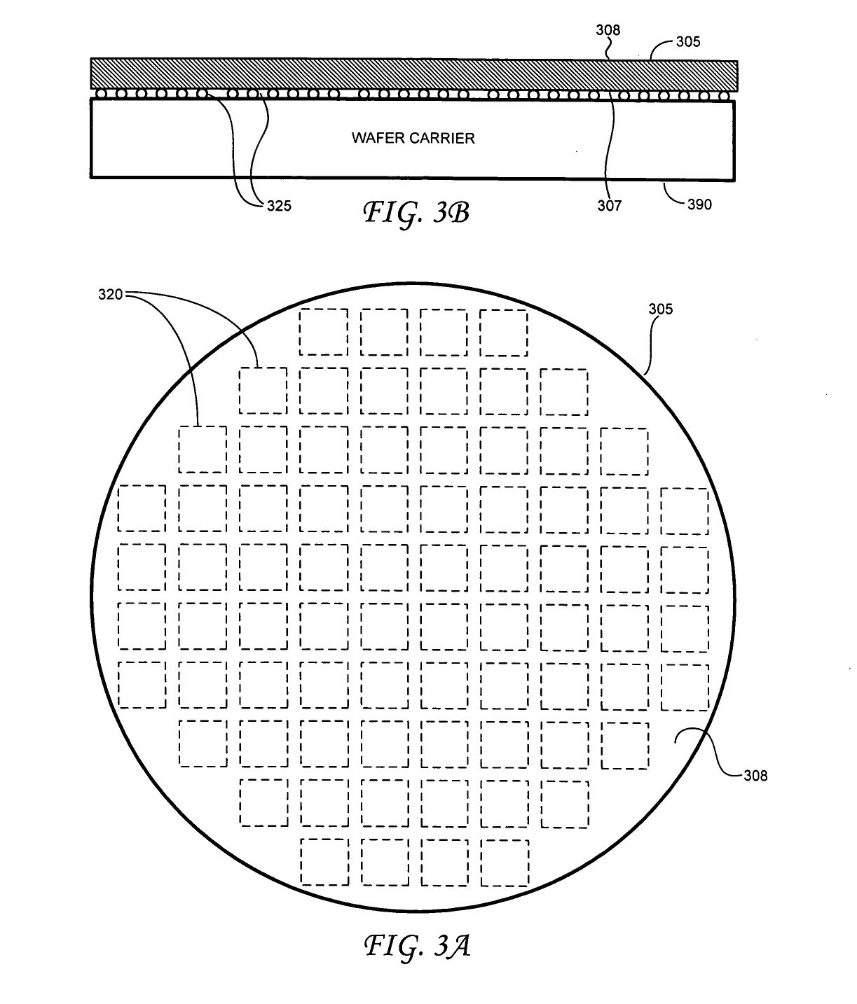

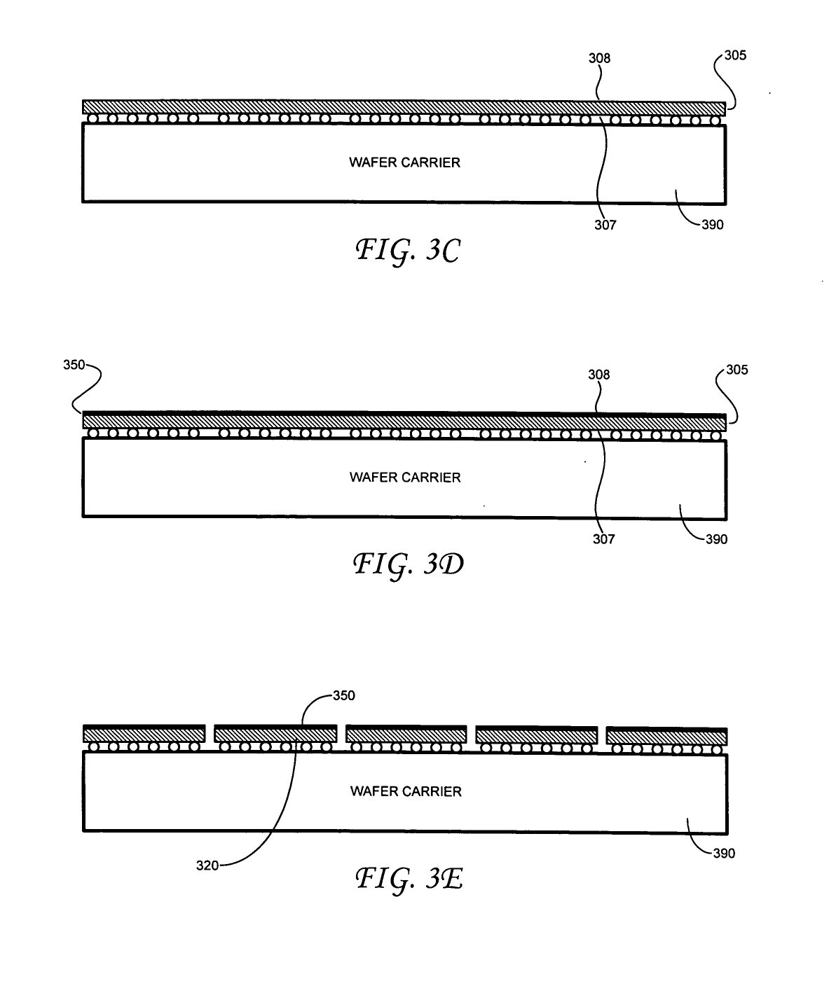

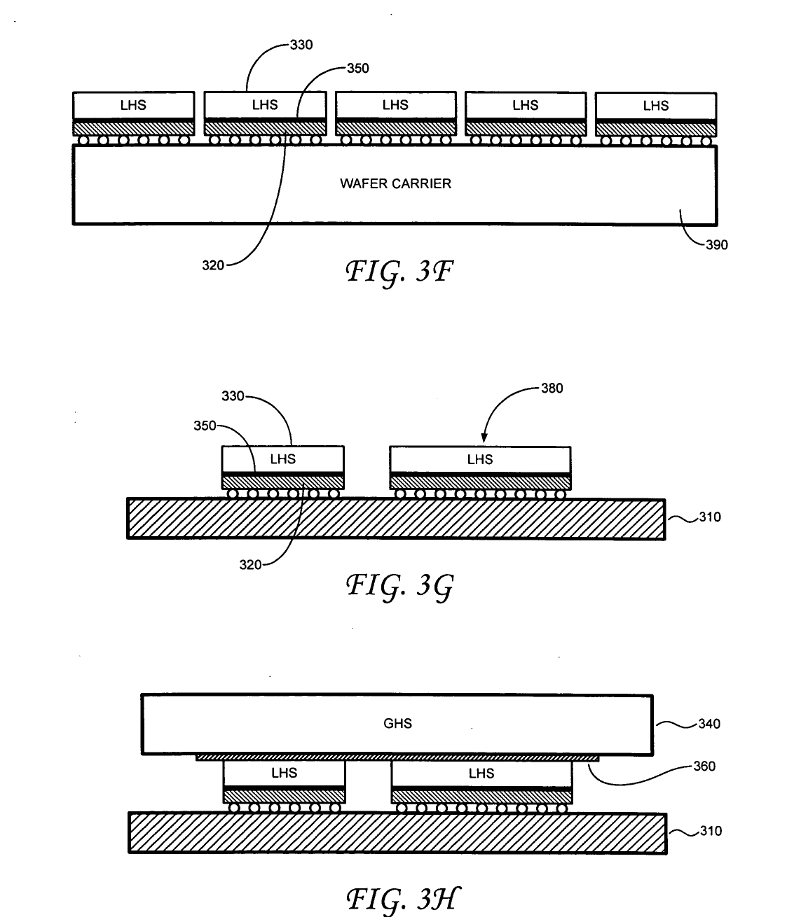

Turning now to FIG. 2, illustrated is an embodiment of a method 200 of fabricating a multi-chip package having two or more heat spreaders (e.g., a package similar to that shown in FIG. 1). The method 200 of FIG. 2 is further illustrated in the schematic diagrams of FIGS. 3A through 3H, and reference should be made to these drawings as called out in the text below.

Referring first to FIGS. 3A and 3B, a semiconductor wafer 305 is shown, and this wafer is disposed on a wafer carrier 390. The semiconductor wafer 305 has a front side 307 and an opposing back side 308. Further, the wafer 305 includes circuitry for a number of IC die 320, as well as a number of metal bumps 325 or other electrically conductive terminals extending from the wafer's front side 307 (wherein a portion of the metal bumps 325 correspond to each of the die 320). The metal bumps 325 will be used to form electrically conductive interconnects for each die 320, as described above. The wafer 305 may comprise any suitable semiconductor material or combination of materials (e.g., silicon, silicon-on-insulator, gallium arsenide, etc.). The wafer carrier 390 may comprise any suitable device capable of supporting the wafer 305 during processing (e.g., thinning, backside metallization, dicing, LHS bonding, etc.).

With reference now to block 210 in FIG. 2, according to one embodiment, the wafer is thinned. This is illustrated in FIG. 3C, where the semiconductor wafer 305 has been thinned at its backside 308. In one embodiment, the original thickness of the wafer 305 may be up to 775 μm, and the wafer is thinned to a final thickness of between approximately 10 μm and 150 μm.

As set forth in block 220, in one embodiment, a metallization layer is formed on a back side of the wafer. This is illustrated in FIG. 3D, where a layer of metal (or multiple, discrete layers of metal) 350 has been formed on the back side 308 of the wafer 305. The back side metallization layer 350 will form the TIM layer on each of the die 320, as previously described.

Referring to block 230, the wafer may then be diced. This is illustrated in FIG. 3E, where the semiconductor wafer 305 has been singulated into a number of individual IC die 320, each die 320 including a portion of the back side metal layer 350. Any suitable process and tools may be utilized to dice the wafer 305.

According to one embodiment, as set forth in block 240, a local heat spreader is attached to each die. This is illustrated in FIG. 3F, where an LHS 330 has been thermally (and mechanically) coupled with each IC die 320. The back side metal layer or TIM 350 may form a bond between each die 320 and its mating LHS 330, as described above. A reflow process may be performed to create the die-to-LHS bonds.

Referring to block 250, in one embodiment, one of the die/LHS assemblies may be attached to a substrate. This is illustrated in FIG. 3G, where an assembly (including a die 320 and LHS 330) has been disposed on a substrate 310 and electrically (and perhaps mechanically) coupled with this substrate. A pick-and-place tool may be used to remove the die/LHS assembly from the wafer carrier 390 (in a manner similar to the removal of a singulated die from a carrier), and an upper surface of each LHS 330 may, in one embodiment, be adapted to be grasped by such a pick-and-place tool. The metal bumps 325 extending from die 320 and mating lands (not shown in figures) on the substrate 310 may be utilized to form electrically conductive interconnects between the die and substrate, as described above. Also, the substrate 310 may be similar to the substrate 110 previously described.

With reference to block 260, in one embodiment, at least one other die/LHS assembly may be disposed on the substrate. This is also illustrated in FIG. 3G, where a second die/LHS assembly 380 has been coupled with the substrate 310. As previously described, any combination of IC die may be disposed on the substrate. In a further embodiment, as set forth in block 265, a layer of an underfill material (not shown in figures) may be disposed between each die and the substrate 310. Any suitable underfill material may be used, and the underfill material may be disposed between a die and the substrate using any suitable method (e.g., capillary flow, etc.).

As set forth in block 270, a global heat spreader may be coupled to each local heat spreader. This is illustrated in FIG. 3H, where a GHS 340 has been thermally coupled with each LHS (e.g., the LHS 330 and the LHS of assembly 380). A TIM layer 360 may be utilized to couple the GHS with each LHS, as described above. Also, as previously noted, a spacer and/or sealant (not shown in FIG. 3H) may be disposed between the GHS 340 and substrate 310.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. An assembly comprising:
a substrate;
a first die coupled with the substrate;
a first local heat spreader (LHS) coupled with the first die;
a second die coupled with the substrate;
a second LHS coupled with the second die; and
a global heat spreader (GHS) coupled with the first LHS and the second LHS.

2. The assembly of claim 1, wherein the first die and the second die are formed by substantially similar process flows.

3. The assembly of claim 2, wherein each of the first die and the second die comprises a processing device.

4. The assembly of claim 1, wherein the first die is formed by one process flow and the second die is formed by a different process flow.

5. The assembly of claim 5, wherein the first die comprises a processing device and the second die comprises a memory device.

6. The assembly of claim 1, wherein the first die and first LHS have a first height (H1) and the second die and second LHS have a second height (H2), wherein H1 substantially equals H2.

7. The assembly of claim 1, wherein the first die and first LHS have a first height (H1) and the second die and second LHS have a second height (H2), wherein H1 and H2 are different.

8. The assembly of claim 1, further comprising a layer of a thermal interface material disposed between the GHS and each of the first LHS and the second LHS.

9. The assembly of claim 1, further comprising a metallization layer disposed between the first die and the first LHS and a metallization layer disposed between the second die and the second LHS.

10. A method comprising:
coupling a first assembly with a substrate, the first assembly including a first die and a first local heat spreader (LHS) coupled with the first die;
coupling a second assembly with the substrate, the second assembly including a die and a second LHS coupled with the second die; and
coupling a global heat spreader (GHS) with the first LHS and with the second LHS.

11. The method of claim 10, wherein the first die is cut from a first wafer formed by one process flow and the second die is cut from a second wafer formed using a different process flow.

12. The method of claim 10, wherein the first die is cut from a first wafer formed by one process flow and the second die is cut from a second wafer formed using a substantially similar process flow.

13. The method of claim 10, wherein the first die and the second die are cut from one wafer.

14. The method of claim 10, further comprising thinning at least the first die at a wafer level prior to singulation.

15. The method of claim 14, further comprising disposing a metallization layer on a backside of the first die prior to singulation.

16. The method of claim 15, further comprising attaching the first LHS to the first die while the first die is held in a carrier, wherein the metallization layer forms a bond between the first die and the first LHS.

17. The method of 10, further comprising:
coupling a third assembly with the substrate, the third assembly including a third die and a third LHS coupled with the third die; and
coupling the GHS with the third LHS.
